(19) United States
(12) Patent Application Publication
(10) Pub. No.: US 2011/0024631 A1
(43) Pub. Date: Feb. 3, 2011

(54) MOTION SENSOR MOUNTING CONFIGURATION

(76) Inventor: Jian Xu, Windsor (CA)

Correspondence Address: Carlson, Gaskey & Olds/Masco Corporation, 400 West Maple Road, Suite 350, Birmingham, MI, 48009, US

(21) Appl. No.: 12/722,803

(22) Filed: Mar. 12, 2010

Related U.S. Application Data
(60) Provisional application No. 61/229,420, filed on Jul. 29, 2009.

(51) Int. Cl. H01L 31/09

(52) U.S. Cl. 250/340; 250/349

(57) ABSTRACT

A method of mounting a sensor in a region includes mounting at least one motion sensor within a region. The at least one motion sensor has a detection area, and has a central axis of detection within the detection area. The at least one motion sensor is oriented so that the central axis of detection diagonally intersects a floor of the region at an angle within a range of 20°-70°.

The application claims priority to U.S. Provisional Application No. 61/229,420 which was filed on Jul. 29, 2009.

### BACKGROUND

This application relates to motion sensors, and more particularly to a mounting configuration for motion sensors.

Motion sensors, such as passive infrared (“PIR”) sensors, are used in various environments to detect motion. Since these sensors have a limited range of detection, blind zones are formed in which no motion is detected.

### SUMMARY

A method of mounting a sensor in a region includes mounting at least one motion sensor within a region. The at least one motion sensor has a detection area, and has a central axis of detection within the detection area. The at least one motion sensor is oriented so that the central axis of detection diagonally intersects a floor of the region at an angle within a range of 20°-70°.

In another feature, the at least one motion sensor includes a first sensing eye and a second sensing eye, and the method includes orienting the first sensing eye so that its central axis of detection diagonally intersects a floor of the region at an angle within a range of 20°-70° and so that the detection area of the first sensing eye covers a first portion of the region, and the method includes orienting the second sensing eye so that its central axis of detection diagonally intersects the floor of the region at an angle within a range of 20°-70° and so that the detection area of the second sensing eye covers a second portion of the region.

A motion sensor configuration for a region defined by a floor and at least one of a ceiling and a wall includes at least one motion sensor mounted within the region. The at least one motion sensor has a range of detection and a central axis of detection within the range of detection. The at least one motion sensor is oriented so that the central axis of detection diagonally intersects the floor of the region at an angle within a range of 20°-70°.

These and other features of the present invention can be best understood from the following specification and drawings, the following of which is a brief description.

### BRIEF DESCRIPTION OF THE DRAWINGS

FIG. 1 schematically illustrates a prior art motion sensor.

FIG. 2 schematically illustrates a first view of a detection area of the sensor of FIG. 1.

FIG. 3 schematically illustrates a second view of the detection area of the sensor of FIG. 1.

FIG. 4 schematically illustrates a prior art ceiling-mounted sensor configuration.

FIG. 5 schematically illustrates a prior art wall-mounted sensor configuration.

FIG. 6 schematically illustrates an improved ceiling-mounted sensor configuration.

FIG. 7 schematically illustrates an improved wall-mounted sensor configuration.

### DETAILED DESCRIPTION

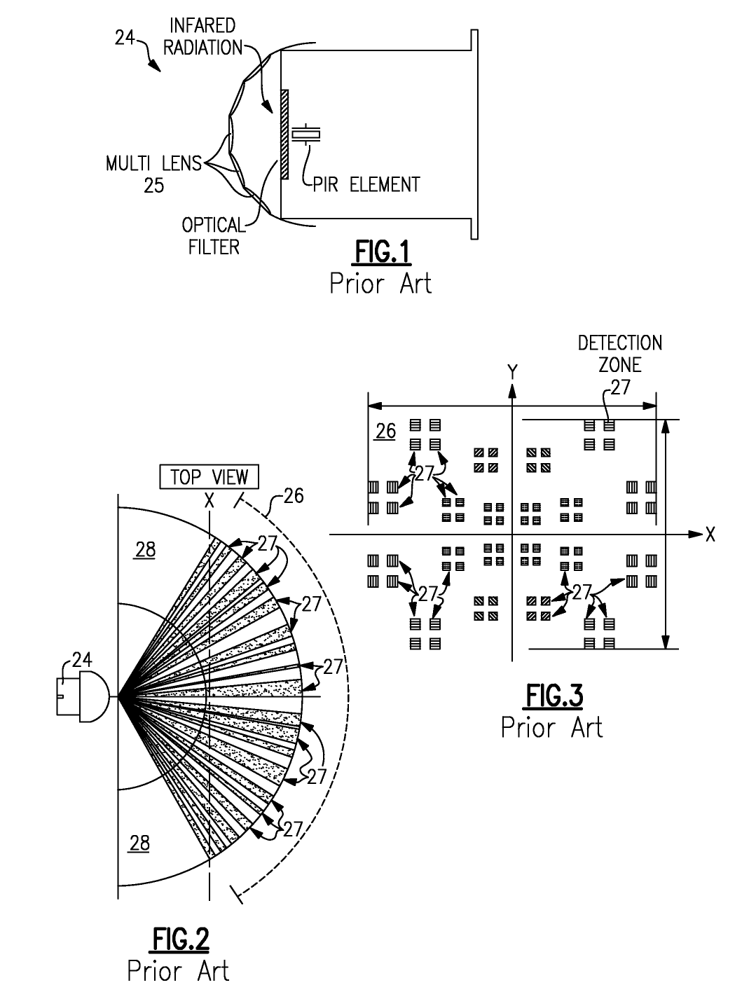

FIG. 1 schematically illustrates an example passive infrared motion sensor 24 available from Panasonic under the model “NaPion.” As a passive infrared motion sensor, the sensor 24 does not emit infrared rays, but rather detects movement from infrared sources, such as humans, such that if an infrared sources moves, the sensor 24 detects the movement and trips a motion detection signal. The sensor 24 includes a plurality of multi lens 25 regions. Each multi lens includes a plurality of lenses that facilitate a detection area 26 of the sensor 24 (see FIG. 2). The Panasonic sensors, and other known motion sensors (e.g., those available from RAB Lighting), are mounted such that a central axis of detection of the sensors is perpendicular to a wall or ceiling, much like a smoke alarm is mounted.

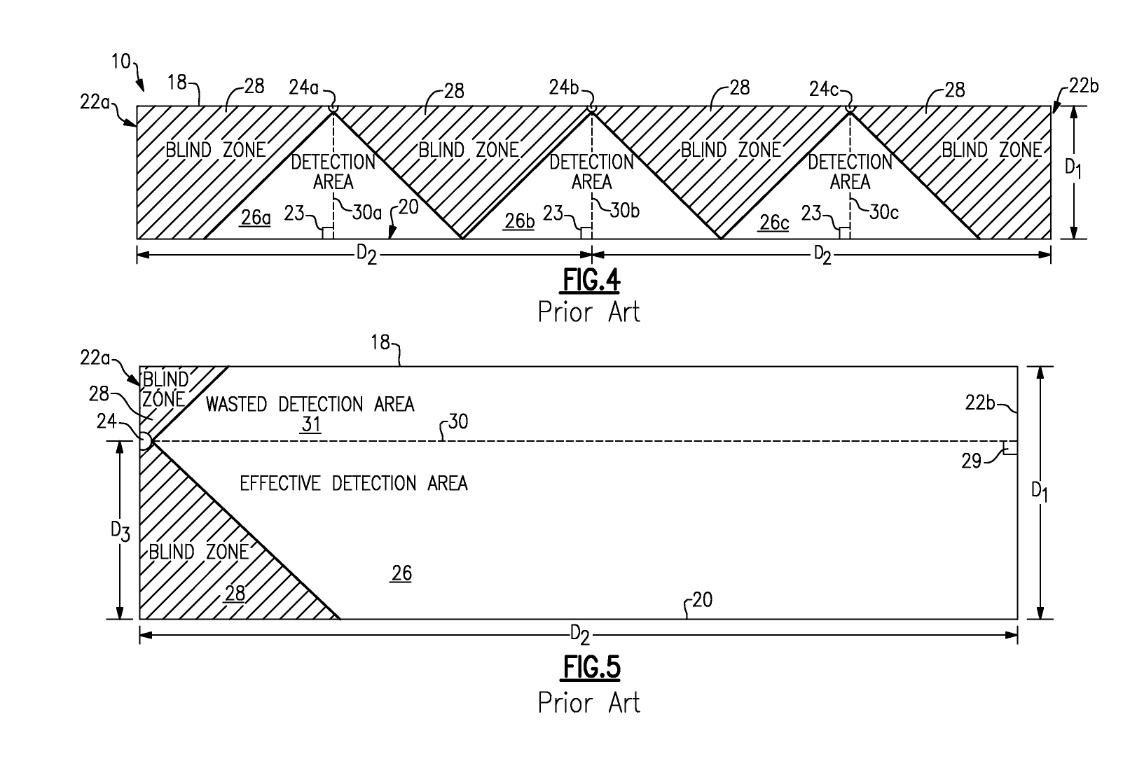

FIG. 2 schematically illustrates a first view of a detection area 26 of the sensor 24. A plurality of detection zones 27 is located within the detection area 26. Each detection zone 27 corresponds to an area within which the sensor 24 is operable to detect movement. Blind zones 28 in which no motion is detected by the sensor 24 are located outside of the detection area 26. FIG. 3 schematically illustrates a second, aerial view of the detection area 26 of the sensor 24 (assuming the sensor 24 is ceiling-mounted). As shown in FIG. 3, the plurality of detection zones 27 is formed throughout the detection area 26.

FIG. 4 schematically illustrates a prior art ceiling-mounted sensor configuration 10 for a region defined by a ceiling 18, a floor 20 and walls 22a-b. The walls 22a-b have a height indicated by “D₁” and the floor has a length of two times “D₂.”

In the configuration 10, a plurality of motion sensors 24a-c is mounted on the ceiling 18. Each sensor 24 has an associated range of detection of approximately 90°, resulting in each sensor 24a-c having an associated detection area 26a-c, and a blind zone 28 in which motion is not detected. In the configuration 10, each sensor 24 is oriented to have a central axis of detection 30a-c that is perpendicular to the floor 20, forming a 90° angle 23 with the floor 20. As shown in FIG. 4, the configuration 10 utilizes three sensors and still does not cover the majority of the region defined by the ceiling 18, floor 20, and walls 22. Thus, if motion was to occur near the outer edges of the region (left of detection area 26a or right of detection area 26c), motion would not be detected.

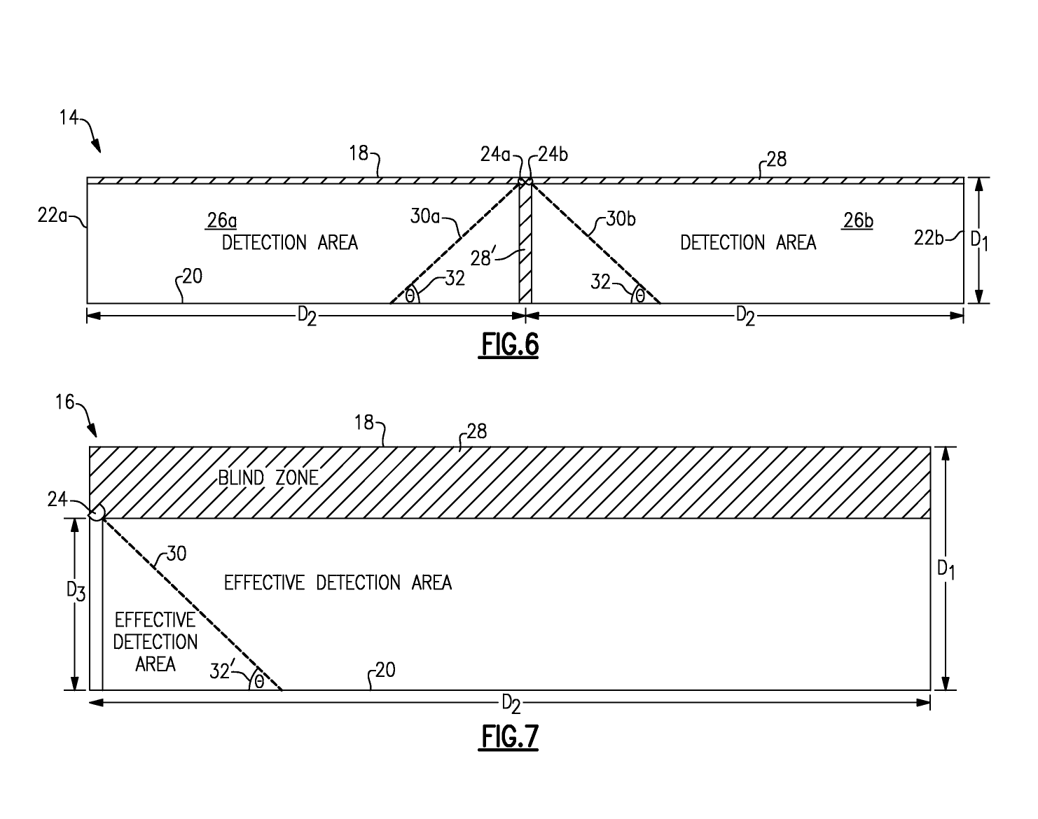

FIG. 5 schematically illustrates a prior art wall-mounted sensor configuration 12 for a region defined by ceiling 18, floor 20 and walls 22a-b. The walls have a height indicated by “D₁” and the floor has a distance of “D₂.” In the configuration 12, a motion sensor 24 is mounted on the wall 22a at a height “D3” above the floor 20. The sensor 24 has an associated range of detection of approximately 90°, resulting an associated detection area 26 and a blind zone 28 in which motion is not detected. The sensor 24 is oriented to have a central axis of detection 30 that is perpendicular to the wall 22b, forming a 90° angle 29 with the wall 22b. Due to the axis of detection 30 forming a 90° angle with the wall 22b, a wasted detection area 31 is formed, having a height of D₁-D₃. Also, a large blind zone 28 is formed, such that motion would not be detected directly beneath the motion sensor 24 of FIG. 5.

FIG. 6 schematically illustrates an improved sensor mounting configuration 14 for the region of FIG. 4, the region being defined by a ceiling 18, a floor 20 and walls 22a-b. Of course the region could also be an outdoor area lacking walls 22 (e.g. a picnic area in a park). In the configuration 14, a plurality of motion sensors 24a-b is mounted on the ceiling 18. The sensors 24a-b have an associated range of detection on the order of 90°-120°, resulting an associated detection area 26 and a blind zone 28 in which motion is not detected. Of course, other ranges of detection would be possible, which could yield varying detection areas and corresponding blind zones.

In the configuration 14, each sensor 24a-b has a corresponding central axis of detection 30a-b that diagonally intersects the floor 20, forming an angle 32 (“θ”) with the floor 20. In one example the angles 32 have a value of approximately 45°. In one example the angles 32 have a value within the range of 20°-70°. In one example the angles 32 have a value within the range of 30°-60°. In one example the angles 32 have a value within the range of 40°-50°. In this configuration 14, the blind zone 28 is negligible, as the detection areas 26a-b cover a majority of the region formed by the ceiling 18, floor 20 and walls 22a-b. As shown in FIG. 3, the sensors 24a-b may be mounted adjacent to each other to minimize a vertical portion 28′ of the blind zone. Also, only two sensors 24a-b are used in the configuration 14, whereas three sensors 24a-c are used in the configuration 10, thus yielding a reduction in sensor quantity, which could provide cost reductions.

Although the configuration 14 illustrates first and second sensors 24a-b, it is understood that the sensors 24a-b could correspond to a single motion sensor that has multiple sensing eyes, such that the sensors 24a-b could be located within a single housing, operable to be mounted on a ceiling or a wall.

FIG. 7 schematically illustrates an improved sensor mounting configuration 16 for the region of FIG. 5, the region being defined by ceiling 18, floor 20 and walls 22a-b. Of course, the region could include only one wall and could omit a ceiling (e.g. the exterior of a building). In the configuration 16, a motion sensor 24 is mounted on the wall 22a at a height “D3” above the floor 20. The sensor 24 has an associated range of detection on the order of 90°-120°, resulting an associated detection area 26 and a blind zone 28 in which motion is not detected. Of course, other ranges of detection would be possible, which could yield varying detection areas and corresponding blind zones.

The sensor 24 is oriented to have a central axis of detection 30 that diagonally intersects the floor 20, forming an angle 32′ (“θ”) with the floor 20. In one example the angle 32 has a value of approximately 45°. In one example the angle 32′ has a value within the range of 20°-70°. In one example the angle 32′ has a value within the range of 30°-60°. In one example the angle 32′ has a value within the range of 40°-50°. In the configuration 14, the blind zone 28 is negligible, as the detection area 26 covers a majority of the region formed by the ceiling 18, floor 20 and walls 22a-b. Also, the wasted detection area 31 of FIG. 5 is a blind zone and the blind zone 28 of FIG. 5 is a detection area.

Although only a single motion sensor 24 is illustrated in FIG. 7, it is understood that the motion sensor 24 could correspond to a single motion sensor having multiple sensing eyes, each sensing eye having a central axis of detection that diagonally intersected floor 20.

The motion sensor 24 diagonal mounting in the configurations 14, 16 could be achieved by a modified “L” bracket bent at a 45° instead of a 90° angle, for example. Also, the motion sensor 24 could be mounted on a rotatable bracket.

Although the sensor 24 has been described as being a PIR sensor having a span of approximately 115° (see FIG. 2), it is understood that other sensors 24 having other sensitivities and ranges could be used.

Although embodiments of this invention have been disclosed, a worker of ordinary skill in this art would recognize that certain modifications would come within the scope of this invention. For that reason, the following claims should be studied to determine the true scope and content of this invention.

What is claimed is:

1. A method of mounting a sensor in a region, comprising:
mounting at least one motion sensor within a region, the at least one motion sensor having a detection area, and having a central axis of detection within the detection area; and
orienting the at least one motion sensor so that the central axis of detection diagonally intersects a floor of the region at an angle within a range of 20°-70°.

2. The method of claim 1, wherein said step of mounting at least one motion sensor within a region includes:
mounting a first motion sensor on a ceiling of the region such that a detection area of the first motion sensor covers a first portion of the region; and
mounting a second motion sensor on the ceiling of the region, the second motion sensor being adjacent to the first motion sensor such that a detection area of the second motion sensor covers a second portion of the region.

3. The method of claim 1, wherein said step of mounting at least one motion sensor within a region includes mounting the at least one motion sensor on a wall of the region.

4. The method of claim 1, wherein the angle has a value within the range of 30°-60°.

5. The method of claim 1, wherein the angle has a value within the range of 40°-50°.

6. The method of claim 1, wherein the angle is a 45° angle.

7. The method of claim 2, wherein the motion sensor is a passive infrared motion sensor.

8. A method of mounting a sensor in a region, comprising:
mounting at least one motion sensor within a region, the at least one motion sensor including a first sensing eye and a second sensing eye, each of the sensing eyes having an associated detection area, and having an associated central axis of detection within the detection area;
orienting the first sensing eye so that its central axis of detection diagonally intersects a floor of the region at an angle within a range of 20°-70° and so that the detection area of the first sensing eye covers a first portion of the region; and
orienting the second sensing eye so that the central axis of detection diagonally intersects the floor of the region at an angle within a range of 20°-70° and so that the detection area of the second sensing eye covers a second portion of the region.

9. The method of claim 8, wherein the central axes of detection of the first sensing eye and the second sensing intersect at an angle of approximately 90°.

10. A motion sensor configuration, comprising:
a region defined by a floor and at least one of a ceiling and a wall; and
at least one motion sensor mounted within the region, the at least one motion sensor having a range of detection and a central axis of detection within the range of detection, the at least one motion sensor being oriented so that the central axis of detection diagonally intersects the floor of the region at an angle within a range of 20°-70°.

11. The configuration of claim 10, wherein the at least one motion sensor includes a first motion sensor and a second motion sensor, the first motion sensor being mounted on a ceiling of the region such that a detection area of the first motion sensor covers a first portion of the region, and the second motion sensor being mounted on the ceiling adjacent to the first motion sensor such that a detection area of the second motion sensor covers a second portion of the region.

12. The configuration of claim 10, wherein the at least one motion sensor is mounted on a wall of the region.

13. The configuration of claim 10, wherein the angle has a value within the range of 30°-60°.

14. The configuration of claim 10, wherein the angle has a value within the range of 40°-50°.

15. The configuration of claim 10, wherein the angle is a 45° angle.

16. The configuration of claim 10, wherein the at least one motion sensor is a passive infrared motion sensor.
